(19) United States
(12) Patent Application Publication
(10) Pub. No.: US 2024/0054951 A1
(43) Pub. Date: Feb. 15, 2024

(54) Pixel Circuit and Driving Method therefor, and Display Apparatus

(71) Applicants: Chengdu BOE Optoelectronics Technology Co., Ltd., Chengdu, Sichuan (CN); BOE Technology Group Co., Ltd., Beijing (CN)

(72) Inventor: Ziyang YU, Beijing (CN)

(21) Appl. No.: 17/764,547

(22) PCT Filed: May 24, 2021
(86) PCT No.: PCT/CN2021/095450

§ 371 Date: Mar. 29, 2022

(51) Int. Cl. G09G 3/3233; G09G 3/3266

(52) U.S. Cl. CPC G09G 3/3233; G09G 3/3266; G09G 2300/0819; G09G 2300/0426; G09G 2300/0842; G09G 2310/08; G09G 2320/0233; G09G 2310/0286

(57) ABSTRACT

A pixel circuit, including a driving sub-circuit, a data writing sub-circuit, a threshold compensation sub-circuit, a storage sub-circuit, a light emitting control sub-circuit, a first initialization sub-circuit, and a second initialization sub-circuit. The data writing sub-circuit is configured to transmit a data signal provided by a data line to a third node under control of a scan line. The threshold compensation sub-circuit is configured to turn on a first node and a second node under control of the scan line to write a threshold voltage of the driving sub-circuit into the storage sub-circuit. The light emitting control sub-circuit is configured to turn on a first power supply line and the second node and turn on the third node and a fourth node under control of a light emitting control line. The first initialization sub-circuit is configured to turn on the first power supply line and the first node.

### CROSS-REFERENCE TO RELATED APPLICATION

The present application is a U.S. National Phase Entry of International Application PCT/CN2021/095450 having an international filing date of May 24, 2021, the contents disclosed in the above-mentioned application are hereby incorporated as a part of this application.

### TECHNICAL FIELD

The present disclosure relates to the field of display technologies, in particular to a pixel circuit and a method for driving the pixel circuit, and a display apparatus.

### BACKGROUND

An Organic Light Emitting Diode (OLED) with advantages such as ultra-thinness, large viewing angle, active light emission, high brightness, continuously adjustable light emission colors, low cost, fast response speed, low power consumption, wide operation temperature range, flexible display, and the like, has gradually become a next-generation display technology with a broad development prospect and has received more and more attention. OLEDs may be divided into a Passive Matrix (PM) type and an Active Matrix (AM) type according to different drive modes. An AMOLED is a current-driven device and controls each sub-pixel by using an independent Thin Film Transistor (TFT), and each sub-pixel may be continuously and independently driven to emit light.

### SUMMARY

The following is a summary of subject matters described herein in detail. The summary is not intended to limit the scope of protection of claims.

Embodiments of the present disclosure provide a pixel circuit and a method for driving the pixel circuit, and a display apparatus.

In an aspect, an embodiment of the present disclosure provides a pixel circuit for driving a light emitting element to emit light, including a driving sub-circuit, a data writing sub-circuit, a threshold compensation sub-circuit, a storage sub-circuit, a light emitting control sub-circuit, a first initialization sub-circuit, and a second initialization sub-circuit. The driving sub-circuit is coupled with a first node, a second node, and a third node, and is configured to provide a driving current to the third node under control of the first node. The data writing sub-circuit is coupled with a data line, a scan line, and the third node, and is configured to transmit a data signal provided by the data line to the third node under control of the scan line. The threshold compensation sub-circuit is coupled with the scan line, the first node, and the second node, and is configured to turn on the first node and the second node under control of the scan line to write a threshold voltage of the driving sub-circuit into the storage sub-circuit. The storage sub-circuit is coupled with the first node and a fourth node. The light emitting control sub-circuit is coupled with a light emitting control line, a first power supply line, the second node, the third node, and the fourth node, and is configured to turn on the first power supply line and the second node and turn on the third node and the fourth node under control of the light emitting control line. The first initialization sub-circuit is coupled with a reset line, the first power supply line, and the first node, and is configured to turn on the first power supply line and the first node under control of the reset line. The second initialization sub-circuit is coupled with the scan line, the reset line, a reference voltage line, and the fourth node, and is configured to turn on the reference voltage line and the fourth node under control of the reset line and turn on the reference voltage line and the fourth node under control of the scan line. A first electrode of the light emitting element is coupled with the fourth node, and a second electrode of the light emitting element is coupled with a second power supply line.

In some exemplary embodiments, a reset line coupled with a pixel circuit located in an n-th row is coupled with a scan line driving a pixel circuit in an (n−1)-th row, wherein n is a positive integer.

In some exemplary embodiments, the pixel circuit further includes a voltage stabilizing sub-circuit coupled with the scan line and the fourth node.

In some exemplary embodiments, the voltage stabilizing sub-circuit includes a voltage stabilizing capacitor; and a first terminal of the voltage stabilizing capacitor is coupled with the fourth node, and a second terminal of the voltage stabilizing capacitor is coupled with the scan line.

In some possible embodiments, the driving sub-circuit includes a Driving Thin Film Transistor (DTFT); and a control electrode of the DTFT is coupled with the first node, a first electrode of the DTFT is coupled with the second node, and a second electrode of the DTFT is coupled with the third node.

In some exemplary embodiments, the first initialization sub-circuit includes a first initialization transistor; and a control electrode of the first initialization transistor is coupled with the reset line, a first electrode of the first initialization transistor is coupled with the first power supply line, and a second electrode of the first initialization transistor is coupled with the first node.

In some exemplary embodiments, the second initialization sub-circuit includes a second initialization transistor and a third initialization transistor. A control electrode of the second initialization transistor is coupled with the reset line, a first electrode of the second initialization transistor is coupled with the reference voltage line, and a second electrode of the second initialization transistor is coupled with the fourth node. A control electrode of the third initialization transistor is coupled with the scan line, a first electrode of the third initialization transistor is coupled with the reference voltage line, and a second electrode of the third initialization transistor is coupled with the fourth node.

In some exemplary embodiments, the threshold compensation sub-circuit includes: a threshold compensation transistor; a control electrode of the threshold compensation transistor is coupled with the scan line, a first electrode of the threshold compensation transistor is coupled with the first node, and a second electrode of the threshold compensation transistor is coupled with the second node.

In some exemplary embodiments, the light emitting control sub-circuit includes a first light emitting control transistor and a second light emitting control second transistor. A control electrode of the first light emitting control transistor is coupled with the light emitting control line, a first electrode of the first light emitting control transistor is coupled with the first power supply line, and a second electrode of the first light emitting control transistor is coupled with the second node. A control electrode of the second light emitting control transistor is coupled with the light emitting control line, a first electrode of the second light emitting control transistor is coupled with the third node, and a second electrode of the second light emitting control transistor is coupled with the fourth node.

In some exemplary embodiments, the data writing sub-circuit includes a data writing transistor; and a control electrode of the data writing transistor is coupled with the scan line, a first electrode of the data writing transistor is coupled with the data line, and a second electrode of the data writing transistor is coupled with the third node.

In some exemplary embodiments, the storage sub-circuit includes a storage capacitor; a first terminal of the storage capacitor is coupled with the first node, and a second terminal of the storage capacitor is coupled with the fourth node.

In some exemplary embodiments, the driving sub-circuit includes a Driving Thin Film Transistor (DTFT); the first initialization sub-circuit includes a first initialization transistor; the second initialization sub-circuit includes a second initialization transistor and a third initialization transistor; the threshold compensation sub-circuit includes a threshold compensation transistor; the light emitting control sub-circuit includes a first light emitting control transistor and a second light emitting control transistor; the data writing sub-circuit includes a data writing transistor; and the storage sub-circuit includes a storage capacitor. A control electrode of the DTFT is coupled with the first node, a first electrode of the DTFT is coupled with the second node, and a second electrode of the DTFT is coupled with the third node. A control electrode of the first initialization transistor is coupled with the reset line, a first electrode of the first initialization transistor is coupled with the first power supply line, and a second electrode of the first initialization transistor is coupled with the first node. A control electrode of the second initialization transistor is coupled with the reset line, a first electrode of the second initialization transistor is coupled with the reference voltage line, and a second electrode of the second initialization transistor is coupled with the fourth node. A control electrode of the third initialization transistor is coupled with the scan line, a first electrode of the third initialization transistor is coupled with the reference voltage line, and a second electrode of the third initialization transistor is coupled with the fourth node. A control electrode of the threshold compensation transistor is coupled with the scan line, a first electrode of the threshold compensation transistor is coupled with the first node, and a second electrode of the threshold compensation transistor is coupled with the second node. A control electrode of the first light emitting control transistor is coupled with the light emitting control line, a first electrode of the first light emitting control transistor is coupled with the first power supply line, and a second electrode of the first light emitting control transistor is coupled with the second node. A control electrode of the second light emitting control transistor is coupled with the light emitting control line, a first electrode of the second light emitting control transistor is coupled with the third node, and a second electrode of the second light emitting control transistor is coupled with the fourth node. A control electrode of the data writing transistor is coupled with the scan line, a first electrode of the data writing transistor is coupled with the data line, and a second electrode of the data writing transistor is coupled with the third node. A first terminal of the storage capacitor is coupled with the first node, and a second terminal of the storage capacitor is coupled with the fourth node.

In some exemplary embodiments, the DTFT, the first initialization transistor, the second initialization transistor, the third initialization transistor, the threshold compensation transistor, the first light emitting control transistor, the second light emitting control transistor, and the data writing transistor are all N-type transistors.

In some exemplary embodiments, the first initialization transistor and the threshold compensation transistor are double-gate transistors.

In another aspect, an embodiment of the present disclosure provides a method for driving a pixel circuit, which is applied to the pixel circuit as described above, including: in an initialization stage, under control of a reset line, a first initialization sub-circuit turning on a first power supply line and a first node and a second initialization sub-circuit turning on a reference voltage line and a fourth node; in a writing stage, under control of a scan line, a data writing sub-circuit transmitting a data signal provided by a data line to a third node, a threshold compensation sub-circuit turning on the first node and a second node to write a threshold voltage of a driving sub-circuit into a storage sub-circuit, and the second initialization sub-circuit turning on the reference voltage line and the fourth node; and in a light emitting stage, under control of a light emitting control line, a light emitting control sub-circuit turning on the first power supply line and the second node and turning on the third node and the fourth node to transmit a driving current output by the driving sub-circuit to a light emitting element.

In another aspect, an embodiment of the present disclosure provides a display apparatus, which includes the aforementioned pixel circuit.

In some exemplary embodiments, the display apparatus further includes: a gate driving circuit. The gate driving circuit includes multiple cascaded first shift register units and multiple cascaded second shift register units. An output terminal of a first shift register unit in an n-th stage is coupled with a scan line driving a pixel circuit in an n-th row; an output terminal of a first shift register unit in an (n−1)-th stage is coupled with a reset line driving the pixel circuit in the n-th row; and an output terminal of a second shift register unit in an n-th stage is coupled with a light emitting control line driving the pixel circuit in the n-th row, wherein n is a positive integer.

Other aspects may be understood upon reading and understanding of the accompanying drawings and detailed descriptions.

### BRIEF DESCRIPTION OF DRAWINGS

Accompanying drawings are used for providing a further understanding of technical solutions of the present disclosure, constitute a part of the specification, and are used for explaining the technical solutions of the present disclosure together with embodiments of the present disclosure, but do not constitute limitations on the technical solutions of the present disclosure. Shapes and sizes of one or more components in the drawings do not reflect actual scales, and are only intended to schematically describe the contents of the present disclosure.

FIG. 1 is a schematic diagram of a structure of a pixel circuit according to at least one embodiment of the present disclosure.

FIG. 2 is a schematic diagram of another structure of a pixel circuit according to at least one embodiment of the present disclosure.

FIG. 3 is an equivalent circuit diagram of a driving sub-circuit of a pixel circuit according to at least one embodiment of the present disclosure.

FIG. 4 is an equivalent circuit diagram of a first initialization sub-circuit of a pixel circuit according to at least one embodiment of the present disclosure.

FIG. 5 is an equivalent circuit diagram of a second initialization sub-circuit of a pixel circuit according to at least one embodiment of the present disclosure.

FIG. 6 is an equivalent circuit diagram of a threshold compensation sub-circuit of a pixel circuit according to at least one embodiment of the present disclosure.

FIG. 7 is an equivalent circuit diagram of a light emitting control sub-circuit of a pixel circuit according to at least one embodiment of the present disclosure.

FIG. 8 is an equivalent circuit diagram of a data writing sub-circuit of a pixel circuit according to at least one embodiment of the present disclosure.

FIG. 9 is an equivalent circuit diagram of a storage sub-circuit of a pixel circuit according to at least one embodiment of the present disclosure.

FIG. 10 is an equivalent circuit diagram of a voltage stabilizing sub-circuit of a pixel circuit according to at least one embodiment of the present disclosure.

FIG. 11 is an equivalent circuit diagram of a pixel circuit according to at least one embodiment of the present disclosure.

FIG. 12 is an operating timing diagram of the pixel circuit provided in FIG. 11.

FIG. 13 is another equivalent circuit diagram of a pixel circuit according to at least one embodiment of the present disclosure.

FIG. 14 is a flowchart of a method for driving a pixel circuit according to at least one embodiment of the present disclosure.

FIG. 15 is a schematic diagram of a display apparatus according to at least one embodiment of the present disclosure.

FIG. 16 is another schematic diagram of a display apparatus according to at least one embodiment of the present disclosure.

### DETAILED DESCRIPTION

The embodiments of the present disclosure will be described below in combination with the drawings in detail. An embodiment may be implemented in multiple different forms. Those of ordinary skills in the art may easily understand such a fact that embodiments and contents may be transformed into one or more forms without departing from the spirit and scope of the present disclosure. Therefore, the present disclosure should not be construed as being limited only to the contents described in following embodiments. The embodiments in the present disclosure and features in the embodiments may be combined randomly with each other if there is no conflict.

In the accompanying drawings, a size of one or more constituent elements, a thickness of a layer, or a region is sometimes exaggerated for clarity. Therefore, one implementation mode of the present disclosure is not necessarily limited to the size, and shapes and sizes of components in the accompanying drawings do not reflect actual scales. In addition, the accompanying drawings schematically show ideal examples, and one implementation mode of the present disclosure is not limited to a shape, a numerical value, or the like shown in the accompanying drawings.

Ordinal numerals such as “first”, “second”, and “third” in the present disclosure are set to avoid confusion between constituents, but not intended for restriction in quantity. In the present disclosure, “plurality/multiple” represents two or more than two.

In the present disclosure, for convenience, wordings “central”, “up”, “down”, “front”, “back”, “vertical”, “horizontal”, “top”, “bottom”, “inside”, “outside”, and the like indicating directional or positional relationships are used for illustrating positional relationships between constituent elements with reference to the accompanying drawings. These terms are not intended to indicate or imply that involved apparatuses or elements must have specific orientations and be structured and operated in the specific orientations but only to facilitate describing the specification and simplifying the description, and thus should not be understood as limitations on the present disclosure. The positional relationships between the constituent elements are changed appropriately according to a direction in which the constituent elements are described. Therefore, it is not limited to the wordings described in the specification, which may be replaced appropriately according to a situation.

In the present disclosure, unless otherwise specified and defined, terms “mounting”, “mutual connection”, “connection”, and “coupling” should be understood in a broad sense. For example, a connection may be a fixed connection, or a detachable connection, or an integral connection. It may be a mechanical connection or an electric connection. It may be a direct connection, or an indirect connection through an intermediate, or an internal communication between two elements. Those of ordinary skills in the art may understand meanings of the above terms in the present disclosure according to situations. Herein, the “electric connection” includes a case where constituent elements are connected together through an element having certain electrical function. The “element having certain electrical function” is not particularly limited as long as electric signals between the connected constituent elements may be transmitted. Examples of the “element having certain electrical function” not only include electrodes and wirings, but also include switching elements such as transistors, resistors, inductors, capacitors, and other elements with one or more functions, etc.

In the present disclosure, a transistor refers to an element at least including three terminals, i.e., a gate electrode, a drain electrode, and a source electrode. The transistor has a channel region between the drain electrode (drain electrode terminal, drain region, or drain electrode) and the source electrode (source electrode terminal, source region, or source electrode), and a current can flow through the drain electrode, the channel region, and the source electrode. In the present disclosure, the channel region refers to a region through which the current mainly flows.

In the present disclosure, to distinguish two electrodes of a transistor except a gate electrode, one of the two electrodes is referred to as a first electrode and the other electrode is referred to as a second electrode. The first electrode may be a source electrode or a drain electrode, and the second electrode may be a drain electrode or a source electrode. In addition, the gate electrode of the transistor is referred to as a control electrode. In a case in which transistors with opposite polarities are used, or a direction of current changes during operation of a circuit, or the like, functions of the “source electrode” and the “drain electrode” are sometimes interchangeable. Therefore, the “source electrode” and the “drain electrode” are interchangeable in the present disclosure.

In the present disclosure, “parallel” refers to a state in which an angle formed by two straight lines is above −10° and below 10°, and thus may include a state in which the angle is above −5° and below 5°. In addition, “perpendicular” refers to a state that an angle formed by two straight lines is above 80° and below 100°, and thus may include a state that the angle is above 85° and below 95°.

In the present disclosure, “about” refers to that a boundary is not defined so strictly and numerical values in process and measurement error ranges are allowed.

An OLED light emitting element achieves light emission by a current-driven method, so a requirement for stability of a current of a Driving Thin Film Transistor (DTFT) and the OLED light emitting element is relatively high. However, due to an influence of preparation processes, stability of a current output by the DTFT is not good, and a threshold voltage Vth of the DTFT will shift under an action of temperature and other factors, thereby affecting display effects and service life of a display apparatus.

The embodiments of the present disclosure provide a pixel circuit and a method for driving the pixel circuit, and a display apparatus, which achieves a compensation for a threshold voltage of a driving sub-circuit to avoid an influence of the threshold voltage on a driving current of a light emitting element, thereby improving display effects.

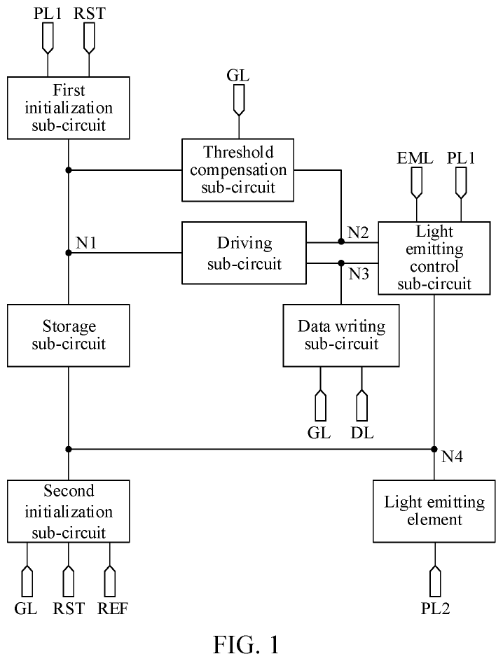

FIG. 1 is a schematic diagram of a structure of a pixel circuit according to at least one embodiment of the present disclosure. As shown in FIG. 1, the pixel circuit according to the exemplary embodiment is used for driving a light emitting element to emit light. The pixel circuit of the embodiment includes a driving sub-circuit, a data writing sub-circuit, a threshold compensation sub-circuit, a storage sub-circuit, a light emitting control sub-circuit, a first initialization sub-circuit, and a second initialization sub-circuit. Among them, the driving sub-circuit is coupled with a first node N1, a second node N2, and a third node N3, and is configured to provide a driving current to the third node N3 under control of the first node N1. The data writing sub-circuit is coupled with a data line DL, a scan line GL, and the third node N3, and is configured to transmit a data signal provided by the data line DL to the third node N3 under control of the scan line GL. The threshold compensation sub-circuit is coupled with the scan line GL, the first node N1, and the second node N2, and is configured to turn on the first node N1 and the second node N2 under control of the scan line GL to write a threshold voltage of the driving sub-circuit into the storage sub-circuit. The storage sub-circuit is coupled with the first node N1 and a fourth node N4. The light emitting control sub-circuit is coupled with a light emitting control line EML, a first power supply line PL1, the second node N2, the third node N3, and the fourth node N4, and is configured to turn on the first power supply line PL1 and the second node N2 and turn on the third node N3 and the fourth node N4 under control of the light emitting control line EML. The first initialization sub-circuit is coupled with a reset line RST, the first power supply line PL1, and the first node N1, and is configured to turn on the first power supply line PL1 and the first node N1 under control of the reset line RST. The second initialization sub-circuit is coupled with the scan line GL, the reset line RST, a reference voltage line REF, and the fourth node N4, and is configured to turn on the reference voltage line REF and the fourth node N4 under control of the reset line RST and to turn on the reference voltage line REF and the fourth node N4 under control of the scan line GL. A first electrode of the light emitting element is coupled with the fourth node N4, and a second electrode of the light emitting element is coupled with a second power supply line PL2.

In some exemplary embodiments, the light emitting element may be an Organic Light Emitting Diode (OLED). The first electrode of the light-emitting element may be an anode and the second electrode of the light-emitting element may be a cathode. However, the embodiments are not limited thereto.

In some exemplary embodiments, the first power supply line PL1 may provide a high-level signal continuously. For example, the first power supply line PL1 provides a first power supply signal ELVDD. The second power supply line PL2 may provide a low-level signal continuously. For example, the second power supply line PL2 provides a second power supply signal ELVSS.

The pixel circuit according to the present embodiment may achieve an internal real-time compensation for a threshold voltage of a driving sub-circuit, thereby avoiding poor display caused by drift of the threshold voltage of the driving sub-circuit.

In some exemplary embodiments, a reset line coupled with a pixel circuit located in an n-th row is coupled with a scan line driving a pixel circuit in an (n−1)-th row, wherein n is a positive integer. In this exemplary embodiment, the scan line driving the pixel circuit in the (n−1)-th row may be multiplexed as a reset line driving the pixel circuit in the n-th row to provide a reset signal to the pixel circuit in the n-th row. In this way, a gate driving circuit only needs to provide two different gates driving signals (i.e., a scan signal and a light emission control signal) to the pixel circuit, which is conducive to simplifying a structure of the gate driving circuit, improving stability of signals, and achieving a narrow bezel of a display apparatus.

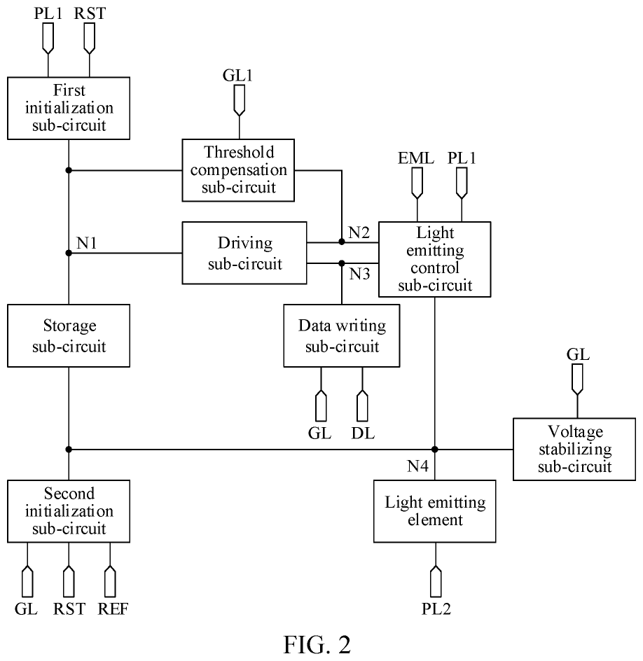

FIG. 2 is a schematic diagram of another structure of a pixel circuit according to at least one embodiment of the present disclosure. In some exemplary embodiments, as shown in FIG. 2, the pixel circuit according to this exemplary embodiment further includes a voltage stabilizing sub-circuit. The voltage stabilizing sub-circuit is coupled with a scan line GL and a fourth node N4. The voltage stabilizing sub-circuit is configured to maintain a voltage of the fourth node N4 to prevent a leakage current of a transistor from affecting a compensation effect on a threshold voltage.

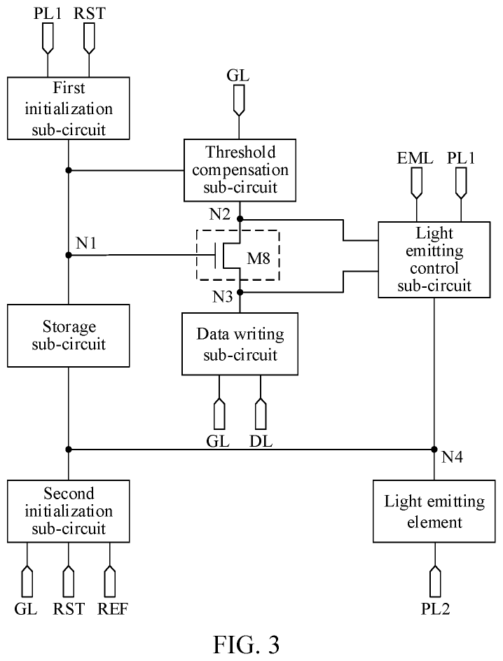

FIG. 3 is an equivalent circuit diagram of a driving sub-circuit of a pixel circuit according to at least one embodiment of the present disclosure. In some exemplary embodiments, as shown in FIG. 3, the driving sub-circuit in the pixel circuit includes a DTFT M8. A control electrode of the DTFT M8 is coupled with a first node N1, a first electrode of the DTFT M8 is coupled with a second node N2, and a second electrode of the DTFT M8 is coupled with a third node N3. The DTFT M8 is configured to provide a driving current to the third node N3 under control of the first node N1.

FIG. 3 illustrates an exemplary structure of the driving sub-circuit. Those skilled in the art may easily understand that embodiments of the driving sub-circuit are not limited thereto as long as its functions can be achieved.

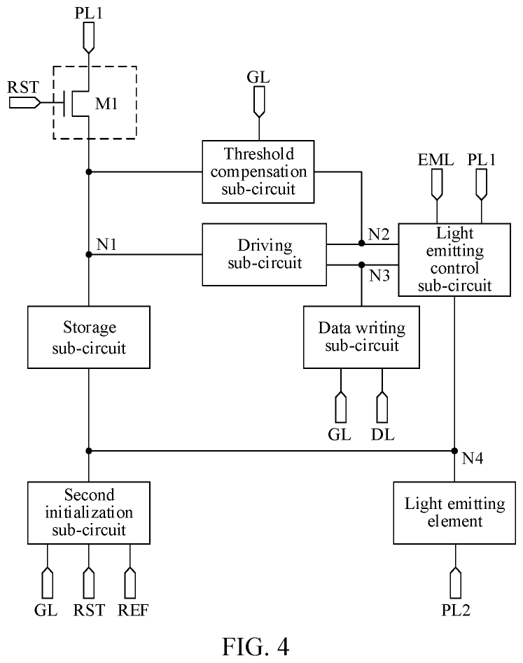

FIG. 4 is an equivalent circuit diagram of a first initialization sub-circuit of a pixel circuit according to at least one embodiment of the present disclosure. In some exemplary embodiments, as shown in FIG. 4, the first initialization sub-circuit in the pixel circuit includes a first initialization transistor M1. A control electrode of the first initialization transistor M1 is coupled with a reset line RST, a first electrode of the first initialization transistor M1 is coupled with a first power supply line PL1, and a second electrode of the first initialization transistor M1 is coupled with a first node N1.

FIG. 4 illustrates an exemplary structure of the first initialization sub-circuit. Those skilled in the art may easily understand that embodiments of the first initialization sub-circuit are not limited thereto as long as its functions can be achieved.

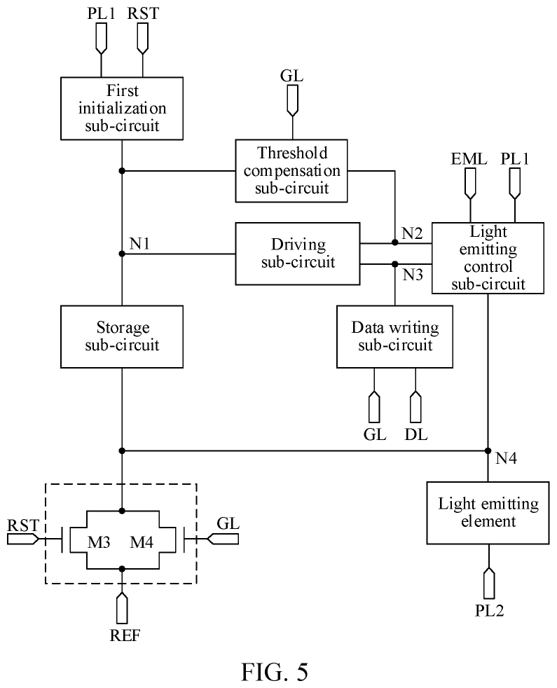

FIG. 5 is an equivalent circuit diagram of a second initialization sub-circuit of a pixel circuit according to at least one embodiment of the present disclosure. In some exemplary embodiments, as shown in FIG. 5, the second initialization sub-circuit in the pixel circuit includes a second initialization transistor M3 and a third initialization transistor M4. A control electrode of the second initialization transistor M3 is coupled with a reset line RST, a first electrode of the second initialization transistor M3 is coupled with a reference voltage line REF, and a second electrode of the second initialization transistor M3 is coupled with a fourth node N4. A control electrode of the third initialization transistor M4 is coupled with a scan line GL, a first electrode of the third initialization transistor M4 is coupled with the reference voltage line REF, and a second electrode of the third initialization transistor M4 is coupled with the second node N4.

FIG. 5 illustrates an exemplary structure of the second initialization sub-circuit. Those skilled in the art may easily understand that embodiments of the second initialization sub-circuit are not limited to this as long as its functions can be achieved.

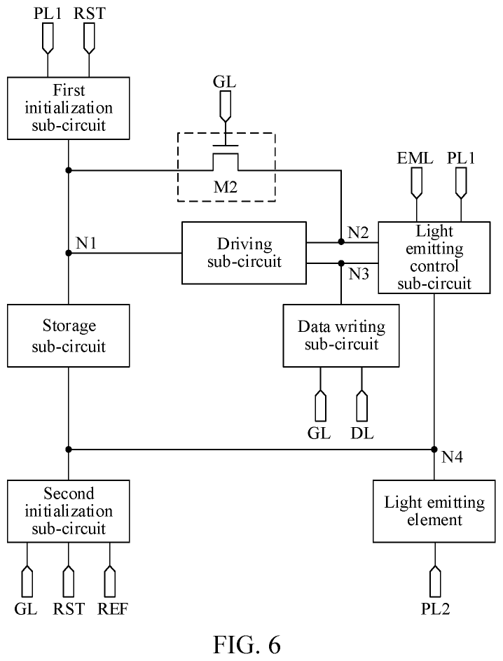

FIG. 6 is an equivalent circuit diagram of a threshold compensation sub-circuit of a pixel circuit according to at least one embodiment of the present disclosure. In some exemplary embodiments, as shown in FIG. 6, the threshold compensation sub-circuit in the pixel circuit includes a threshold compensation transistor M2. A control electrode of the threshold compensation transistor M2 is coupled with a scan line GL, a first electrode of the threshold compensation transistor M2 is coupled with a first node N1, and a second electrode of the threshold compensation transistor M2 is coupled with a second node N2.

FIG. 6 illustrates an exemplary structure of the threshold compensation sub-circuit. Those skilled in the art may easily understand that embodiments of the threshold compensation sub-circuit are not limited thereto as long as its functions can be achieved.

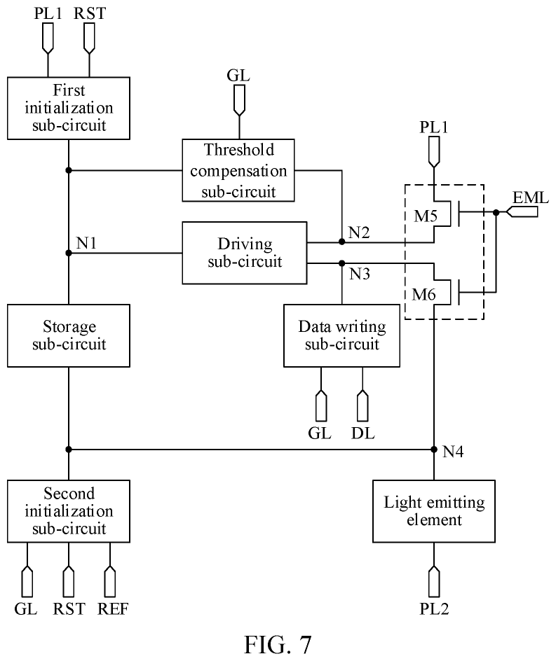

FIG. 7 is an equivalent circuit diagram of a light emitting control sub-circuit of a pixel circuit according to at least one embodiment of the present disclosure. In some exemplary embodiments, as shown in FIG. 7, the light emitting control sub-circuit in the pixel circuit includes a first light emitting control transistor M5 and a second light emitting control transistor M6. A control electrode of the first light emitting control transistor M5 is coupled with a light emitting control line EML, a first electrode of the first light emitting control transistor M5 is coupled with a first power supply line PL1, and a second electrode of the first light emitting control transistor M5 is coupled with a second node N2. A control electrode of the second light emitting control transistor M6 is coupled with the light emitting control line EML, a first electrode of the second light emitting control transistor M6 is coupled with a third node N3, and a second electrode of the second light emitting control transistor M6 is coupled with a fourth node N4.

FIG. 7 illustrates an exemplary structure of the light emitting control sub-circuit. Those skilled in the art may easily understand that embodiments of the light emitting control sub-circuit are not limited thereto as long as its functions can be achieved.

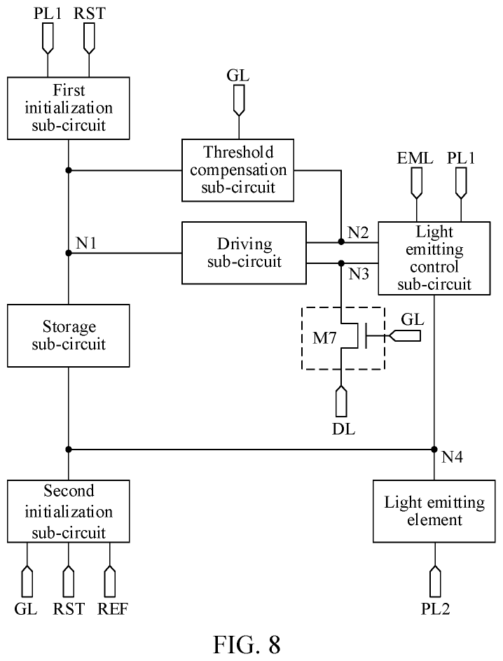

FIG. 8 is an equivalent circuit diagram of a data writing sub-circuit of a pixel circuit according to at least one embodiment of the present disclosure. In some exemplary embodiments, as shown in FIG. 8, the data writing sub-circuit in the pixel circuit includes a data writing transistor M7. A control electrode of the data writing transistor M7 is coupled with a scan line GL, a first electrode of the data writing transistor M7 is coupled with a data line DL, and a second electrode of the data writing transistor M7 is coupled with a third node N3.

FIG. 8 illustrates an exemplary structure of the data writing sub-circuit. Those skilled in the art may easily understand that embodiments of the data writing sub-circuit are not limited thereto as long as its functions can be achieved.

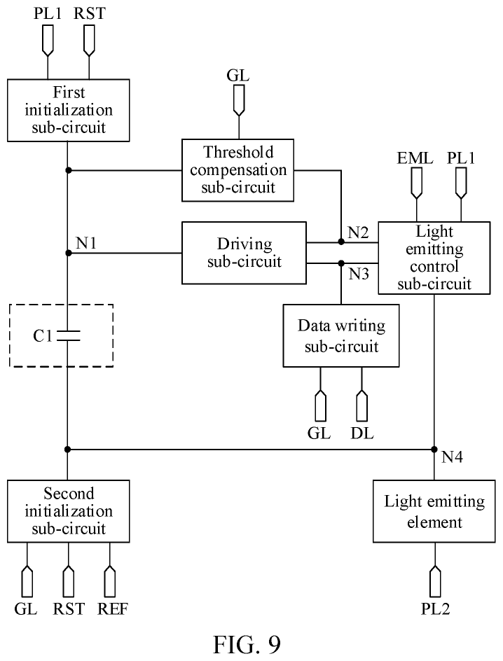

FIG. 9 is an equivalent circuit diagram of a storage sub-circuit of a pixel circuit according to at least one embodiment of the present disclosure. In some exemplary embodiments, as shown in FIG. 9, the storage sub-circuit in the pixel circuit includes a storage capacitor C1. A first terminal of the storage capacitor C1 is coupled with a first node N1, and a second terminal of the storage capacitor C1 is coupled with a fourth node N4.

FIG. 9 illustrates an exemplary structure of the storage sub-circuit. Those skilled in the art may easily understand that embodiments of the storage sub-circuit are not limited thereto as long as its functions can be achieved.

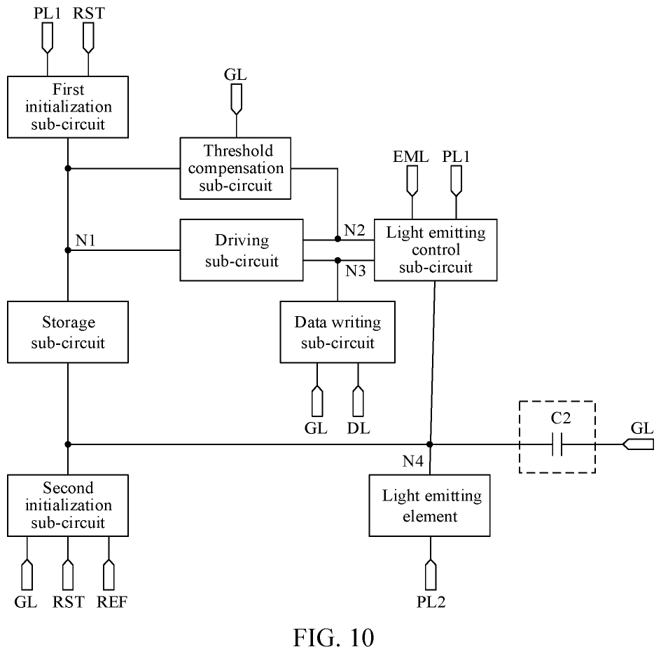

FIG. 10 is an equivalent circuit diagram of a voltage stabilizing sub-circuit of a pixel circuit according to at least one embodiment of the present disclosure. In some exemplary embodiments, as shown in FIG. 10, the voltage stabilizing sub-circuit in the pixel circuit includes a voltage stabilizing capacitor C2. A first terminal of the voltage stabilizing capacitor C2 is coupled with a fourth node N4, and a second terminal of the voltage stabilizing capacitor C2 is coupled with a scan line GL.

FIG. 10 illustrates an exemplary structure of the voltage stabilizing sub-circuit. Those skilled in the art may easily understand that embodiments of the voltage stabilizing sub-circuit are not limited thereto as long as its functions can be achieved.

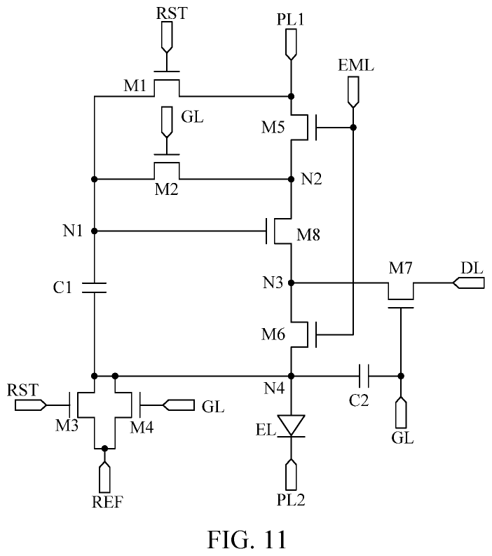

FIG. 11 is an equivalent circuit diagram of a pixel circuit according to at least one embodiment of the present disclosure. In some exemplary embodiments, as shown in FIG. 11, a driving sub-circuit includes a DTFT M8. A first initialization sub-circuit includes a first initialization transistor M1. A threshold compensation sub-circuit includes a threshold compensation transistor M2. A second initialization sub-circuit includes a second initialization transistor M3 and a third initialization transistor M4. A light emitting control sub-circuit includes a first light emitting control transistor M5 and a second light emitting control transistor M6. A data writing sub-circuit includes a data writing transistor M7. A storage sub-circuit includes a storage capacitor C1. A voltage stabilizing sub-circuit includes a voltage stabilizing capacitor C2.

In some exemplary embodiments, as shown in FIG. 11, a control electrode of the DTFT M8 is coupled with a first node N1, a first electrode of the DTFT M8 is coupled with a second node N2, and a second electrode of the DTFT M8 is coupled with a third node N3. A control electrode of the first initialization transistor M1 is coupled with a reset line RST, a first electrode of the first initialization transistor M1 is coupled with a first power supply line PL1, and a second electrode of the first initialization transistor M1 is coupled with the first node N1. A control electrode of the second initialization transistor M3 is coupled with the reset line RST, a first electrode of the second initialization transistor M3 is coupled with a reference voltage line REF, and a second electrode of the second initialization transistor M3 is coupled with a fourth node N4. A control electrode of the third initialization transistor M4 is coupled with a scan line GL, a first electrode of the third initialization transistor M4 is coupled with the reference voltage line REF, and a second electrode of the third initialization transistor M4 is coupled with the fourth node N4. A control electrode of the threshold compensation transistor M2 is coupled with the scan line GL, a first electrode of the threshold compensation transistor M2 is coupled with the first node N1, and a second electrode of the threshold compensation transistor M2 is coupled with the second node N2. A control electrode of the first light emitting control transistor M5 is coupled with a light emitting control line EML, a first electrode of the first light emitting control transistor M5 is coupled with the first power supply line PL1, and a second electrode of the first light emitting control transistor M5 is coupled with the second node N2. A control electrode of the second light emitting control transistor M6 is coupled with the light emitting control terminal EML, a first electrode of the second light emitting control transistor M6 is coupled with the third node N3, and a second electrode of the second light emitting control transistor M6 is coupled with the fourth node N4. A control electrode of the data writing transistor M7 is coupled with the scan line GL, a first electrode of the data writing transistor M7 is coupled with a data line DL, and a second electrode of the data writing transistor M7 is coupled with the third node N3. A first terminal of the storage capacitor C1 is coupled with the first node N1, and a second terminal of the storage capacitor C1 is coupled with the fourth node N4. A first terminal of the voltage stabilizing capacitor C2 is coupled with the fourth node N4, and a second terminal of the voltage stabilizing capacitor C2 is coupled with the scan line GL. A first electrode of a light emitting element EL is coupled with the fourth node N4, and a second electrode of the light emitting element EL is coupled with a second power supply line PL2.

In some exemplary embodiments, the transistors from M1 to M8 in the pixel circuit may be P-type transistors or may be N-type transistors. Use of a same type of transistors in the pixel circuit may simplify a process flow, reduce a process difficulty of a display substrate, and improve a yield of a product. In some possible embodiments, multiple transistors in the pixel circuit may include P-type transistors and N-type transistors. This embodiment is not limited thereto.

In some exemplary embodiments, the transistors from M1 to M8 in the pixel circuit may be low temperature poly-silicon thin film transistors, or may be oxide thin film transistors, or may be low temperature poly-silicon thin film transistors and oxide thin film transistors. An active layer of a low temperature poly-silicon thin film transistor is made of Low Temperature Poly-Silicon (LTPS), and an active layer of an oxide thin film transistor is made of an oxide semiconductor (Oxide). A Low-temperature Poly-Silicon thin film transistor has advantages of high mobility, fast charging, and etc., and an oxide thin film transistor has advantages of low leakage current, etc. The low temperature poly-silicon thin film transistor and the oxide thin film transistor are integrated on a display substrate to form a Low Temperature Polycrystalline Oxide (LTPO) display substrate, and advantages of both the low temperature poly-silicon thin film transistor and the oxide thin film transistor may be utilized to achieve low frequency driving, which may reduce power consumption, and may improve display quality.

Solutions of the embodiment are further described below through an operation process of the pixel circuit provided in FIG. 11.

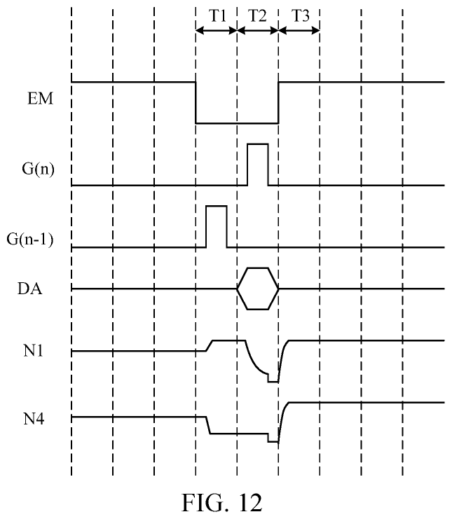

The operation process of the pixel circuit provided in FIG. 11 is illustrated by taking a case that the transistors in the pixel circuit provided in FIG. 11 are all N-type thin film transistors as an example. FIG. 12 is an operating timing diagram of the pixel circuit shown in FIG. 11. As shown in FIG. 11, the pixel circuit involved in this exemplary embodiment includes eight transistor units (i.e., transistors from M1 to M8), two capacitor units (i.e., the storage capacitor C1 and the voltage stabilizing capacitor C2), five input terminals (i.e., the data line DL, the scan line GL, the reset line RST, the light emitting control line EML, the reference voltage line REF), and two power supply terminals (i.e., the first power supply line PL1 and the second power supply line PL2). Among them, the first power supply line PL1 provides a high-level signal continuously, such as a first power supply signal ELVDD, and the second power supply line PL2 provides a low-level signal continuously, such as a second power supply signal ELVSS.

In this exemplary embodiment, a scan line GL(n) driving a pixel circuit in an n-th row is configured to provide a scan signal G(n). A scan line GL(n−1) driving a pixel circuit in an (n−1)-th row may be multiplexed as a reset line RST driving the pixel circuit in the n-th row and configured to provide a reset signal to the pixel circuit in the n-th row. That is, the reset signal provided by the reset line RST of the pixel circuit in the n-th row is the scan signal G(n−1), wherein n is a positive integer.

As shown in FIG. 12, in a time period of one frame, the operation process of the pixel circuit includes following stages: an initialization stage T1, a writing stage T2, and a light emitting stage T3.

In a first stage T1, i.e. the initialization stage, as shown in FIG. 12, a light emitting control signal EM provided by the light emitting control line EML is at a low level, and the first light emitting control transistor M5 and the second light emitting control transistor M6 are turned off. A scan signal G(n) providing by the scan line GL is at a low level, and the threshold compensation transistor M2, the data writing transistor M7, and the third initialization transistor M4 are turned off. A reset signal (i.e., the scan signal G(n−1)) provided by the reset line RST is at a high level, and the first initialization transistor M1 and the second initialization transistor M3 are turned on. The first initialization transistor M1 and the second initialization transistor M3 are turned on to initialize both terminals of the storage capacitor C1 (i.e. the first node N1 and the fourth node N4). The first initialization transistor M1 turns on the first node N1 and the first power supply line PL1, such that a voltage V_{N1} of the first node N1 is equal to ELVDD, wherein ELVDD is a first power supply signal provided by the first power supply line PL1. The second initialization transistor M3 turns on the fourth node N4 and the reference voltage line REF, such that a voltage V_{N4} of the fourth node N4 is equal to Vref, wherein Vref is the reference voltage provided by the reference voltage line REF.

In a second stage T2, i.e. the writing stage, as shown in FIG. 12, the light emitting control signal EM provided by the light emitting control line EML is at a low level, and the first light emitting control transistor M5 and the second light emitting control transistor M6 are turned off. A reset signal (i.e., the scan signal G(n−1)) provided by the reset line RST is at a low level, and the first initialization transistor M1 and the second initialization transistor M3 are turned off. A scan signal G(n) provided by the scan line GL is at a high level, and the threshold compensation transistor M2, the third initialization transistor M4, and the data writing transistor M7 are turned on. The threshold compensation transistor M2 and the data writing transistor M7 are turned on, such that the data line DL establishes a path with the first node N1 through the data writing transistor M7, the DTFT M5, and the threshold compensation transistor M2. The threshold compensation transistor M2 turns on the first node N1 and the second node N2, and the DTFT M8 forms a diode structure. A charge of the first node N1 passes through the threshold compensation transistor M2, the DTFT M3, and the data writing transistor M7 and flows to the data line DL until the voltage V_{N1} of the first node N1 is equal to Vdata+Vth, wherein Vth is a threshold voltage of the DTFT M8 and Vdata is a voltage of a data signal DA transmitted by the data line DL. The third initialization transistor M4 is turned on, and the reference voltage line REF is turned on with the fourth node N4, such that the voltage of the fourth node N4 is maintained to be the reference voltage Vref, i.e., V_{N4}=Vref.

In this stage, although the DTFT M8 is turned on and a driving current is generated, since the second light emitting control transistor M6 is turned off, the driving current cannot flow into the light emitting element EL, so the light emitting element EL does not emit light.

In a third stage T3, i.e. the light emitting stage, as shown in FIG. 12, a reset signal (i.e. a scan signal G(n−1)) provided by the reset line RST is at a low level, and the first initialization transistor M1 and the second initialization transistor M3 are turned off. A scan signal G(n) provide by the scan line GL is at a low level, and the threshold compensation transistor M2, the third initialization transistor M4, and the data writing transistor M7 are turned off. The light emitting control signal EM provided by the light emitting control line EML is at a high level, and the first light emitting control transistor M5 and the second light emitting control transistor M6 are turned on. Under a holding effect of a voltage of the storage capacitor C1, a gate-source voltage of the DTFT M8 is Vgs=V_{N1}−V_{N4}=Vdata+Vth−Vref. A driving current generated by the DTFT M8 flows into the light emitting element EL through the second light emitting control transistor M6. A driving current Id output by the DTFT M8 may be obtained through a following formula.

$$Id = \frac{1}{2} * μ * {C}_{o x} * \frac{W}{L} * {( {V}_{g s} - {V}_{t h} )}^{2} = \frac{K}{2} {( V data - V ref )}^{2}$$

Among them,

$$K = \frac{W}{L} μ {C}_{ox} ,$$

μ is a channel mobility of the DTFT, W and L are a channel width and a channel length of the DTFT respectively, Cₒₓ is a channel capacitance per unit area of the DTFT. Vgs is a gate-source voltage difference of the DTFT. Vth is a threshold voltage of the DTFT. Vdata is a voltage of the data signal DA transmitted by the data line DL. Vref is a reference voltage provided by the reference voltage line REF.

It may be seen from the formula described above that the driving current has nothing to do with the threshold voltage Vth of the DTFT but only depends on the voltage of the data signal DA provided by the data line DL and the reference voltage Vref provided by the reference voltage line REF. Therefore, an influence of a threshold voltage of a DTFT on a driving current is eliminated, display brightness uniformity of a display apparatus is further ensured, and a display effect is improved.

In this exemplary embodiment, storage and compensation functions for a threshold voltage of a DTFT may be achieved by utilizing a pixel circuit including eight transistors and two capacitors, thereby eliminating an influence of the threshold voltage of the DTFT on a driving current.

In this exemplary embodiment, both terminals of the voltage stabilizing capacitor C2 are respectively connected with the fourth node N2 and the scan line GL, which may stabilize a potential of the fourth node N4 and prevent a leakage current of a transistor from affecting a compensation effect.

In some exemplary embodiments, the voltage of the data signal DA transmitted by the data line DL may be about 0V to 5V, and the threshold voltage Vth of the DTFT may be about −1V to 1V. However, the embodiments are not limited thereto.

The pixel circuit of this exemplary embodiment may achieve internal compensation for a threshold voltage, thereby improving a display effect. Moreover, by multiplexing a scan signal as a reset signal, a structure of a gate driving circuit may be simplified, which is conducive to achieving a design of a narrow bezel. In addition, N-type thin film transistors are adopted in the pixel circuit of this exemplary embodiment, which may improve a problem of short-term afterimage and the like caused by hysteresis of P-type transistors.

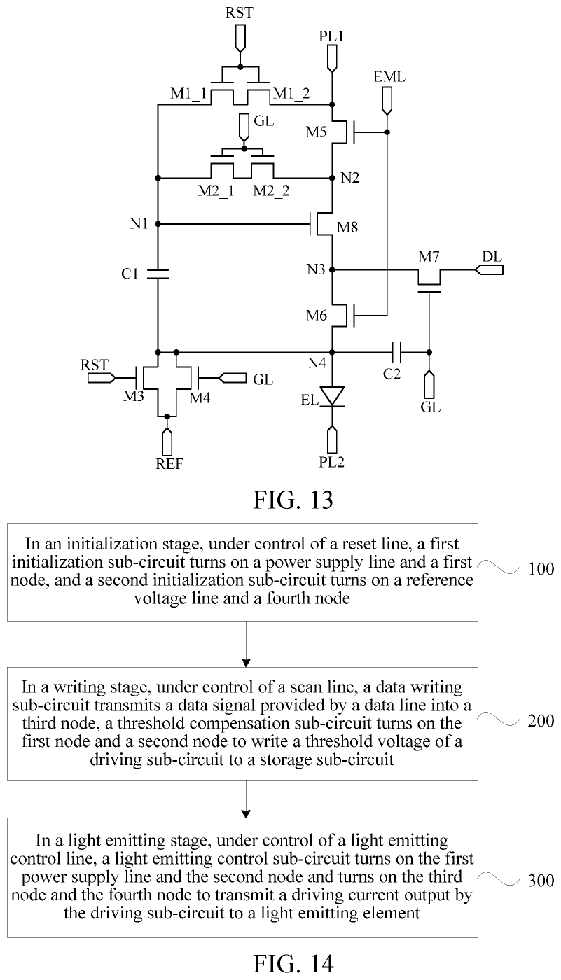

FIG. 13 is another equivalent circuit diagram of a pixel circuit according to at least one embodiment of the present disclosure. In some exemplary embodiments, as shown in FIG. 13, a first initialization transistor M1 and a threshold compensation transistor M2 may be double-gate transistors. In this example, the first initialization transistor M1 includes two first sub-transistors M1_1 and M1_2. A control electrode of the first sub-transistor M1_1 is coupled with a control electrode of the first sub-transistor M1_2 and is coupled with a reset line RST. A first electrode of the first sub-transistor M1_1 is coupled with a first node N1, a second electrode of the first sub-transistor M1_1 is coupled with a first electrode of the first sub-transistor M1_2, and a second electrode of the first sub-transistor M1_2 is coupled with a first power supply line PL1. The threshold compensation transistor M2 includes two second sub-transistors M2_1 and M2_2. A control electrode of the second sub-transistor M2_1 is coupled with a control electrode of the second sub-transistor M2_2 and is coupled with a scan line GL. A first electrode of the second sub-transistor M2_1 is coupled with the first node N1, a second electrode of the second sub-transistor M2_1 is coupled with a first electrode of the second sub-transistor M2_2, and a second electrode of the second sub-transistor M2_2 is coupled with a second node N2.

According to this exemplary embodiment, by using a double-gate structure for the first initialization transistor and the threshold compensation transistor, a leakage current of the threshold compensation transistor to the first node in the initialization stage and the light emitting stage may be reduced, and a leakage current of the first initialization transistor to the first node in the writing stage and the light emitting stage may be reduced, thereby preventing a leakage current of a transistor from affecting a compensation effect.

Rest of the structure and an operating timing of the pixel circuit of this embodiment may refer to descriptions in the aforementioned embodiments, and thus will not be repeated here.

At least one embodiment of the present disclosure further provides a method for driving a pixel circuit. FIG. 14 is a flowchart of a method for driving a pixel circuit according to at least one embodiment of the present disclosure. As shown in FIG. 14, the method for driving the pixel circuit according to an embodiment of the present disclosure includes following steps.

In step 100, in an initialization stage, under control of a reset line, a first initialization sub-circuit turns on a first power supply line and a first node, and a second initialization sub-circuit turns on a reference voltage line and a fourth node.

In step 200, in a writing stage, under control of a scan line, a data writing sub-circuit transmits a data signal provided by a data line to a third node, a threshold compensation sub-circuit turns on the first node and a second node to write a threshold voltage of a driving sub-circuit into a storage sub-circuit, and the second initialization sub-circuit turns on the reference voltage line and the fourth node.

In step 300, in a light emitting stage, under control of a light emitting control line, a light emitting control sub-circuit turns on the first power supply line and the second node and turns on the third node and the fourth node to transmit a driving current output by the driving sub-circuit to a light emitting element.

The method for driving the pixel circuit according to this exemplary embodiment is used in the pixel circuit according to the aforementioned embodiments, and an implementation principle and effect thereof are similar and thus will not be repeated here.

At least one embodiment of the present disclosure further provides a display apparatus, which includes a pixel circuit. An implementation principle and effect for the pixel circuit are similar to that of the aforementioned embodiments and thus will not be repeated here.

In some exemplary embodiments, the display apparatus may include a display substrate on which a pixel circuit may be disposed. The display substrate may be an OLED display substrate. The display apparatus may be any product or component with a display function, such as an OLED display apparatus, a mobile phone, a tablet computer, a television, a monitor, a laptop computer, a digital photo frame, and a navigator. However, the embodiments are not limited thereto.

In some exemplary embodiments, the display apparatus further includes: a gate driving circuit. The gate driving circuit includes multiple cascaded first shift register units and multiple cascaded second shift register units. An output terminal of a first shift register unit in an n-th stage is coupled with a scan line driving a pixel circuit in an n-th row. An output terminal of a first shift register unit in an (n−1)-th stage is coupled with a reset line driving the pixel circuit in the n-th row. An output terminal of a second shift register unit in an n-th stage is coupled with a light emitting control line driving the pixel circuit in the n-th row, wherein n is a positive integer.

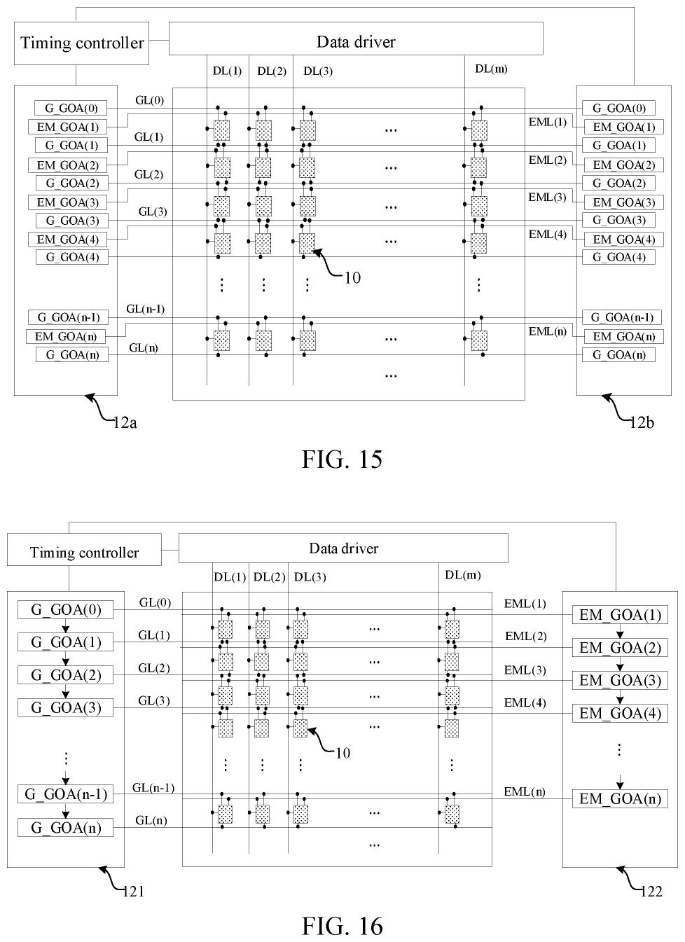

FIG. 15 is a schematic diagram of a display apparatus according to at least one embodiment of the present disclosure. In some exemplary embodiments, as shown in FIG. 15, the display apparatus includes multiple pixel circuits 10, multiple scan lines (e.g., scan lines GL(0) to GL(n)), multiple light emitting control lines (e.g., light emitting control lines EML(1) to EML(n)), multiple data lines (e.g., data lines DL(1) to DL(m)), gate driving circuits 12a and 12b, a data driver, and a timing controller, wherein n and m are positive integers.

In some examples, the multiple pixel circuits 10 are located in a display region of the display apparatus, and the gate driving circuit 12a and the gate driving circuit 12b are located on two opposite sides of the display region. For example, the gate driving circuit 12a is located on a left side of the display region and the gate driving circuit 12b is located on a right side of the display region. The gate driving circuit 12a is illustrated as an example. The gate driving circuit 12a includes multiple cascaded first shift register units G_GOA and multiple cascaded second shift register units EM_GOA. An output terminal of a first shift register unit G_GOA(n) in an n-th stage is coupled with a scan line GL(n) driving a pixel circuit in an n-th row. An output terminal of a first shift register unit G_GOA(n−1) in an (n−1)-th stage is coupled with a reset line driving the pixel circuit in the n-th row. An output terminal of a second shift register unit EM_GOA(n) in an n-th stage is coupled with a light emitting control line EML(n) for driving the pixel circuit in the n-th row. A structure of the gate driving circuit 12b may be referred to a structure of the gate driving circuit 12a, and thus will not be repeated here.

In some exemplary embodiments, the timing controller may provide the data driver with a gray scale value and a control signal suitable for specifications of the data driver, and may provide a clock signal, a scan start signal, an emission stop signal, and the like suitable for specifications of a gate driving circuit to the gate driving circuit. The data driver may generate a data voltage to be supplied to the data lines DL(1) to DL(m) by utilizing a gray scale value and a control signal received from the timing controller. For example, the data driver may sample the gray scale value by utilizing the clock signal and apply a data voltage corresponding to the gray scale value to the data lines DL(1) to DL(m) by taking a pixel row as a unit. Multiple cascaded first shift register units of the gate driving circuit may generate a scan signal to be supplied to the scan lines GL(0) to GL(n) by receiving a clock signal, a scan start signal, and the like from the timing controller. Multiple cascaded second shift register units of the gate driving circuit may generate a light emitting control signal to be supplied to the light emitting control lines EML(1) to EML(n) by receiving a clock signal, an emission stop signal, and the like from the timing controller.

In this exemplary embodiment, a gate driving circuit only needs to provide a scan signal and a light emitting control signal to a pixel circuit, thus a structure is simple and signal stability is good, which is conducive to achieving a design of a narrow bezel.

FIG. 16 is another schematic diagram of a display apparatus according to at least one embodiment of the present disclosure. In some exemplary embodiments, as shown in FIG. 16, a gate driving circuit includes a first group of shift register units 121 and a second group of shift register units 122. The first group of shift register units 121 includes multiple cascaded first shift register units G_GOA and is configured to generate a scan signal. The second group of shift register units 122 includes multiple cascaded second shift register units EM_GOA and is configured to generate a light emitting control signal. The first group of shift register units 121 and the second group of shift register units 122 may be located on two opposite sides of a display region.

Rest of a structure of the display apparatus of the embodiment may refer to description of the embodiment in FIG. 15, and thus will not be repeated here.

The drawings of the present disclosure only involve the structures involved in the present disclosure, and other structures may refer to conventional designs. The embodiments in the present disclosure, and features in the embodiments may be combined with each other to obtain new embodiments if there is no conflict.

Those of ordinary skills in the art should understand that modifications or equivalent replacements may be made to the technical solutions of the present disclosure without departing from the spirit and scope of the technical solutions of the present disclosure, and should be included in the scope of the claims of the present disclosure.

1. A pixel circuit, which is configured to drive a light emitting element to emit light, and the pixel circuit comprises:
a driving sub-circuit, a data writing sub-circuit, a threshold compensation sub-circuit, a storage sub-circuit, a light emitting control sub-circuit, a first initialization sub-circuit, and a second initialization sub-circuit;
wherein the driving sub-circuit is coupled with a first node, a second node, and a third node, and is configured to provide a driving current to the third node under control of the first node;
the data writing sub-circuit is coupled with a data line, a scan line, and the third node, and is configured to transmit a data signal provided by the data line to the third node under control of the scan line;
the threshold compensation sub-circuit is coupled with the scan line, the first node, and the second node, and is configured to turn on the first node and the second node under control of the scan line to write a threshold voltage of the driving sub-circuit into the storage sub -circuit;
the storage sub-circuit is coupled with the first node and a fourth node;
the light emitting control sub-circuit is coupled with a light emitting control line, a first power supply line, the second node, the third node, and the fourth node, and is configured to turn on the first power supply line and the second node and turn on the third node and the fourth node under control of the light emitting control line;
the first initialization sub-circuit is coupled with a reset line, the first power supply line, and the first node, and is configured to turn on the first power supply line and the first node under control of the reset line;
the second initialization sub-circuit is coupled with the scan line, the reset line, a reference voltage line, and the fourth node, and is configured to turn on the reference voltage line and the fourth node under control of the reset line and turn on the reference voltage line and the fourth node under control of the scan line; and
a first electrode of the light emitting element is coupled with the fourth node, and a second electrode of the light emitting element is coupled with a second power supply line.

2. The pixel circuit according to claim 1, wherein a reset line coupled with a pixel circuit located in an n-th row is coupled with a scan line driving a pixel circuit in an (n−1)-th row, wherein n is a positive integer.

3. The pixel circuit according to claim 1, further comprising: a voltage stabilizing sub-circuit coupled with the scan line and the fourth node.

4. The pixel circuit according to claim 3, wherein the voltage stabilizing sub-circuit comprises: a voltage stabilizing capacitor; a first terminal of the voltage stabilizing capacitor is coupled with the fourth node, and a second terminal of the voltage stabilizing capacitor is coupled with the scan line.

5. The pixel circuit according to claim 1, wherein the driving sub-circuit comprises: a Driving Thin Film Transistor (DTFT); a control electrode of the DTFT is coupled with the first node, a first electrode of the DTFT is coupled with the second node, and a second electrode of the DTFT is coupled with the third node.

6. The pixel circuit according to claim 1, wherein the first initialization sub-circuit comprises: a first initialization transistor; a control electrode of the first initialization transistor is coupled with the reset line, a first electrode of the first initialization transistor is coupled with the first power supply line, and a second electrode of the first initialization transistor is coupled with the first node.

7. The pixel circuit according to claim 1, wherein the second initialization sub-circuit comprises: a second initialization transistor and a third initialization transistor;
a control electrode of the second initialization transistor is coupled with the reset line, a first electrode of the second initialization transistor is coupled with the reference voltage line, and a second electrode of the second initialization transistor is coupled with the fourth node; and
a control electrode of the third initialization transistor is coupled with the scan line, a first electrode of the third initialization transistor is coupled with the reference voltage line, and a second electrode of the third initialization transistor is coupled with the fourth node.

8. The pixel circuit according to claim 1, wherein the threshold compensation sub-circuit comprises: a threshold compensation transistor; a control electrode of the threshold compensation transistor is coupled with the scan line, a first electrode of the threshold compensation transistor is coupled with the first node, and a second electrode of the threshold compensation transistor is coupled with the second node.

9. The pixel circuit according to claim 1, wherein the light emitting control sub-circuit comprises: a first light emitting control transistor and a second light emitting control transistor;
a control electrode of the first light emitting control transistor is coupled with the light emitting control line, a first electrode of the first light emitting control transistor is coupled with the first power supply line, and a second electrode of the first light emitting control transistor is coupled with the second node; and
a control electrode of the second light emitting control transistor is coupled with the light emitting control line, a first electrode of the second light emitting control transistor is coupled with the third node, and a second electrode of the second light emitting control transistor is coupled with the fourth node.

10. The pixel circuit according to claim 1, wherein the data writing sub-circuit comprises: a data writing transistor; a control electrode of the data writing transistor is coupled with the scan line, a first electrode of the data writing transistor is coupled with the data line, and a second electrode of the data writing transistor is coupled with the third node.

11. The pixel circuit according to claim 1, wherein the storage sub-circuit comprises: a storage capacitor; a first terminal of the storage capacitor is coupled with the first node, and a second terminal of the storage capacitor is coupled with the fourth node.

12. The pixel circuit according to claim 1, wherein the driving sub-circuit comprises: a Driving Thin Film Transistor (DTFT); the first initialization sub-circuit comprises a first initialization transistor; the second initialization sub-circuit comprises a second initialization transistor and a third initialization transistor; the threshold compensation sub-circuit comprises a threshold compensation transistor; the light emitting control sub-circuit comprises a first light emitting control transistor and a second light emitting control transistor; the data writing sub-circuit comprises a data writing transistor; and the storage sub-circuit comprises a storage capacitor;
a control electrode of the DTFT is coupled with the first node, a first electrode of the DTFT is coupled with the second node, and a second electrode of the DTFT is coupled with the third node;
a control electrode of the first initialization transistor is coupled with the reset line, a first electrode of the first initialization transistor is coupled with the first power supply line, and a second electrode of the first initialization transistor is coupled with the first node;
a control electrode of the second initialization transistor is coupled with the reset line, a first electrode of the second initialization transistor is coupled with the reference voltage line, and a second electrode of the second initialization transistor is coupled with the fourth node;
a control electrode of the third initialization transistor is coupled with the scan line, a first electrode of the third initialization transistor is coupled with the reference voltage line, and a second electrode of the third initialization transistor is coupled with the fourth node;
a control electrode of the threshold compensation transistor is coupled with the scan line, a first electrode of the threshold compensation transistor is coupled with the first node, and a second electrode of the threshold compensation transistor is coupled with the second node;
a control electrode of the first light emitting control transistor is coupled with the light emitting control line, a first electrode of the first light emitting control transistor is coupled with the first power supply line, and a second electrode of the first light emitting control transistor is coupled with the second node;
a control electrode of the second light emitting control transistor is coupled with the light emitting control line, a first electrode of the second light emitting control transistor is coupled with the third node, and a second electrode of the second light emitting control transistor is coupled with the fourth node;
a control electrode of the data writing transistor is coupled with the scan line, a first electrode of the data writing transistor is coupled with the data line, and a second electrode of the data writing transistor is coupled with the third node; and
a first terminal of the storage capacitor is coupled with the first node, and a second terminal of the storage capacitor is coupled with the fourth node.

13. The pixel circuit according to claim 12, wherein the DTFT, the first initialization transistor, the second initialization transistor, the third initialization transistor, the threshold compensation transistor, the first light emitting control transistor, the second light emitting control transistor, and the data writing transistor are all N-type transistors.

14. The pixel circuit according to claim 12, wherein the first initialization transistor and the threshold compensation transistor are double-gate transistors.

15. A method for driving a pixel circuit, applied to the pixel circuit according to claim 1, the method comprising:
in a initialization stage, under control of a reset line, a first initialization sub-circuit turning on a first power supply line and a first node and a second initialization sub-circuit turning on a reference voltage line and a fourth node;
in a writing stage, under control of a scan line, a data writing sub-circuit transmitting a data signal provided by a data line to a third node, a threshold compensation sub-circuit turning on the first node and a second node to write a threshold voltage of a driving sub-circuit into a storage sub-circuit, and the second initialization sub-circuit turning on the reference voltage line and the fourth node; and
in a light emitting stage, under control of a light emitting control line, a light emitting control sub-circuit turning on the first power supply line and the second node and turning on the third node and the fourth node to transmit a driving current output by the driving sub-circuit to a light emitting element.

16. A display apparatus, comprising the pixel circuit according to claim 1.

17. The display apparatus according to claim 16, further comprising: a gate driving circuit;
the gate driving circuit comprises a plurality of cascaded first shift register units and a plurality of cascaded second shift register units;
an output terminal of a first shift register unit in an n-th stage is coupled with a scan line driving a pixel circuit in an n-th row; an output terminal of a first shift register unit in an (n−1)-th stage is coupled with a reset line driving the pixel circuit in the n-th row; and an output terminal of a second shift register unit in an n-th stage is coupled with a light emitting control line driving the pixel circuit in the n-th row, wherein n is a positive integer.

18. The pixel circuit according to claim 2, further comprising: a voltage stabilizing sub-circuit coupled with the scan line and the fourth node.

19. The pixel circuit according to claim 2, wherein the driving sub-circuit comprises: a Driving Thin Film Transistor (DTFT); a control electrode of the DTFT is coupled with the first node, a first electrode of the DTFT is coupled with the second node, and a second electrode of the DTFT is coupled with the third node.

20. The pixel circuit according to claim 3, wherein the driving sub-circuit comprises: a Driving Thin Film Transistor (DTFT); a control electrode of the DTFT is coupled with the first node, a first electrode of the DTFT is coupled with the second node, and a second electrode of the DTFT is coupled with the third node.
